(19) United States
(12) Patent Application Publication
(10) Pub. No.: US 2026/0293161 A1
(43) Pub. Date: Sep. 24, 2026

(54) SEMICONDUCTOR MEMORY DEVICE AND SEMICONDUCTOR PACKAGE INCLUDING THE SAME

(71) Applicant: Samsung Electronics Co., Ltd., Suwon-si (KR)

(72) Inventors: Su Min PARK, Suwon-si (KR); Dong-Chan LIM, Suwon-si (KR)

(21) Appl. No.: 19/399,357

(22) Filed: Nov. 24, 2025

(30) Foreign Application Priority Data
Mar. 19, 2025 (KR) 10-2025-0035032

(51) Int. Cl. H10B 80/00; H10B 12/00; H10W 90/00; H10W 90/20; H10W 90/26

(52) U.S. Cl. CPC H10B 80/00; H10B 12/30; H10W 90/26; H10W 90/291; H10W 90/297; H10W 90/724; H10W 90/792

(57) ABSTRACT

A semiconductor memory device according to some implementations of the present disclosure includes a memory cell structure including a cell substrate, a peripheral circuit structure overlapping the memory cell structure in a first direction perpendicular to an upper surface of the cell substrate, a plurality of semiconductor structures stacked in the first direction, and a plurality of through electrodes extending in the first direction in each of the plurality of semiconductor structures. The memory cell structure includes a semiconductor pattern including a channel region and a capacitor structure on one side of the semiconductor pattern, a plurality of memory cells stacked and spaced apart on the cell substrate in the first direction, a plurality of word lines extending in a second direction parallel to the upper surface of the cell substrate and surrounding the channel region, and a bit line on an opposite side of the semiconductor pattern.

### CROSS-REFERENCE TO RELATED APPLICATION

This application claims priority to Korean Patent Applications No. 10-2025-0035032, filed in the Korean Intellectual Property Office on Mar. 19, 2025, the entire contents of which are hereby incorporated herein by reference.

### TECHNICAL FIELD

The present disclosure relates to a semiconductor memory device and a semiconductor package including the same.

### BACKGROUND

A semiconductor memory device is mainly used to store and retrieve data. A semiconductor memory device may be used in electronic apparatuses in a variety of fields such as computers, communication equipment, and consumer electronics. As the electronics industry has advanced dramatically and user demands have diversified, electronic apparatuses have become smaller, multifunctional, and higher-capacity.

To increase the performance of semiconductor memory devices, the integration density of semiconductor memory devices has been increasing. During this development, several transistor structures such as vertical-channel transistors and vertical-stack transistors have been proposed.

### SUMMARY

An object of some implementations of the present disclosure is to provide a semiconductor memory device and a semiconductor package whose integration density, electrical performance, and reliability are improved.

According to some implementations of the present disclosure, a semiconductor memory device may include a plurality of semiconductor structures that are stacked in a first direction that is perpendicular to an upper surface of a cell substrate, each semiconductor structure of the plurality of semiconductor structures comprising a memory cell structure including the cell substrate, and a peripheral circuit structure that overlaps the memory cell structure in the first direction, and a plurality of through electrodes that extend in the first direction in each of the plurality of semiconductor structures. The memory cell structure may include a plurality of memory cells that are stacked on the cell substrate and spaced apart in the first direction, each memory cell of the plurality of memory cells including a semiconductor pattern having a channel region and a capacitor structure on a first side of the semiconductor pattern, a plurality of word lines that extend in a second direction parallel to the upper surface of the cell substrate and that surround the channel region, and a bit line on a second side of the semiconductor pattern that is opposite to the first side of the semiconductor pattern.

According to some implementations of the present disclosure, a semiconductor memory device may include a first semiconductor structure including a first memory cell structure and a first peripheral circuit structure that overlaps the first memory cell structure in a first direction, a second semiconductor structure that is stacked on the first semiconductor structure in the first direction, the second semiconductor structure including a second memory cell structure and a second peripheral circuit structure that overlaps the second memory cell structure in the first direction, a first through electrode that extends into the first memory cell structure and the first peripheral circuit structure in the first direction, and a second through electrode that extends into the second memory cell structure and the second peripheral circuit structure in the first direction and that is aligned with the first through electrode in the first direction. Each of the first and second memory cell structures may include a plurality of memory cells that are stacked and spaced apart from one another in the first direction, each memory cell of the plurality of memory cells including a semiconductor pattern including a channel region, a first source/drain region and a second source/drain region respectively on opposite sides of the channel region, and a capacitor structure connected to the first source/drain region, a plurality of word lines that extend in a second direction that intersects with the first direction, wherein the plurality of word lines are stacked and spaced apart from one another in the first direction, wherein the plurality of word lines surround the channel region of each memory cells of the plurality of memory cells, and a bit line that extends in the first direction and connected to the second source/drain region.

According to some implementations of the present disclosure, a semiconductor package may include a package substrate, a semiconductor memory device including a plurality of semiconductor structures that are stacked on the package substrate in a first direction that is perpendicular to an upper surface of the package substrate, and a plurality of through electrodes that are electrically connected to the plurality of semiconductor structures. Each semiconductor structure of the plurality of semiconductor structures may include a memory cell structure including a cell substrate, a peripheral circuit structure that overlaps the memory cell structure in the first direction, and a wiring structure that is electrically connected to both the memory cell structure and the peripheral circuit structure. Further, the memory cell structure may include a plurality of memory cells that are spaced apart from one another in the first direction, each memory cell of the plurality of memory cells having a semiconductor pattern including a channel region, a first source/drain region and a second source/drain region disposed on opposite sides of the channel region, and a capacitor structure connected to the first source/drain region, a plurality of word lines that extend in a second direction that intersects with the first direction and that are spaced apart from one another in the first direction, where the plurality of word lines surround the channel region, and a bit line that extends in the first direction and is connected to the second source/drain region.

According to some implementations of the present disclosure, a method of manufacturing a semiconductor memory device may include fabricating a plurality of semiconductor structures by stacking a peripheral circuit structure on a memory cell structure including a cell substrate such that the peripheral circuit structure overlaps the cell substrate in a first direction perpendicular to an upper surface of the cell substrate, forming a through electrode that penetrates at least part of each of the plurality of semiconductor structures in the first direction, and stacking the plurality of semiconductor structures. The memory cell structure may include a plurality of memory cells stacked on the cell substrate spaced apart in the first direction, each memory cell including a semiconductor pattern having a channel region and a capacitor structure disposed on one side of the semiconductor pattern, a plurality of word lines extending in a second direction parallel to the upper surface of the cell substrate and surrounding the channel region, and a bit line disposed on an opposite side of the semiconductor pattern.

In some implementations, the through electrode may include a first surface and a second surface opposite the first surface, and a width of the through electrode may decrease from the first surface toward the second surface along the first direction.

In some implementations, the method may further include forming first and second connection pads electrically connected to the through electrode at a position overlapping the first surface of the through electrode in the first direction.

In some implementations, the second connection pad may be disposed on the second surface of the through electrode.

In some implementations, each semiconductor structure may further include a first bonding insulating layer that overlaps the first connection pad in the second direction and a second bonding insulating layer that overlaps the second connection pad in the second direction.

In some implementations, the plurality of semiconductor structures may include a first semiconductor structure and a second semiconductor structure stacked on the first semiconductor structure, and stacking the plurality of semiconductor structures may include bonding the first connection pad of the first semiconductor structure to the first connection pad of the second semiconductor structure and bonding the first bonding insulating layer of the first semiconductor structure to the second bonding insulating layer of the second semiconductor structure.

In some implementations, the plurality of semiconductor structures may include a first semiconductor structure and a second semiconductor structure stacked on the first semiconductor structure, and stacking the plurality of semiconductor structures may include bonding the second connection pad of the first semiconductor structure to the first connection pad of the second semiconductor structure and bonding the second bonding insulating layer of the first semiconductor structure to the first bonding insulating layer of the second semiconductor structure.

In some implementations, the memory cell structure may further include a cell bonding insulating layer and a cell bonding pad overlapping the cell bonding insulating layer in the second direction, and the peripheral circuit structure may further include a peripheral bonding insulating layer and a peripheral bonding pad overlapping the peripheral bonding insulating layer in the second direction. Fabricating the plurality of semiconductor structures may include bonding the cell bonding insulating layer to the peripheral bonding insulating layer and bonding the cell bonding pad to the peripheral bonding pad.

In some implementations, fabricating the plurality of semiconductor structures may include stacking the peripheral circuit structure on the memory cell structure.

In some implementations, fabricating the plurality of semiconductor structures may include stacking the memory cell structure on the peripheral circuit structure.

According to some implementations of the present disclosure, the semiconductor memory device and the semiconductor package may improve integration density, electrical performance, and reliability.

### BRIEF DESCRIPTION OF THE DRAWINGS

FIG. 1 illustrates a semiconductor package according to some implementations of the present disclosure.

FIG. 2 is a perspective view illustrating components of a memory cell structure according to some implementations of the present disclosure.

FIG. 3 is a cross-sectional view illustrating a semiconductor structure according to some implementations of the present disclosure.

FIGS. 4, 5, 6, 7, and 8 are cross-sectional views illustrating a method of manufacturing a semiconductor structure according to some implementations of the present disclosure.

FIGS. 9, 10, 11, and 12 are diagrams illustrating example semiconductor memory devices in which the semiconductor structure of FIG. 3 is stacked.

FIG. 13 is a cross-sectional view illustrating a semiconductor structure according to some implementations of the present disclosure.

FIGS. 14, 15, 16, and 17 are cross-sectional views illustrating a method of manufacturing a semiconductor structure according to some implementations of the present disclosure.

FIGS. 18, 19, 20, and 21 are diagrams illustrating example stacked memory devices in which the semiconductor structure of FIG. 13 is stacked.

FIGS. 22, 23, and 24 are diagrams illustrating an example semiconductor structure and semiconductor memory devices according to some implementations of the present disclosure.

FIGS. 25, 26, and 27 are diagrams illustrating an example semiconductor structure and semiconductor memory devices according to some implementations of the present disclosure.

### DETAILED DESCRIPTION

Hereinafter, a stacked memory device and a semiconductor package according to some implementations of the present disclosure will be described in detail with reference to the drawings.

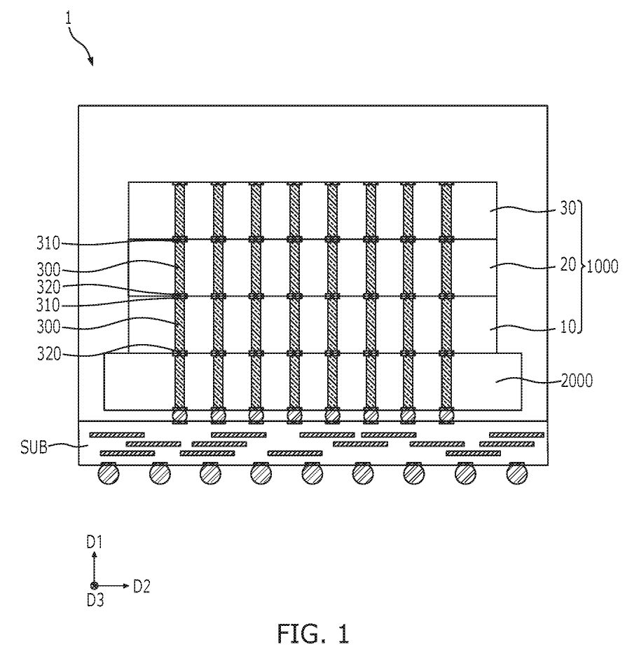

FIG. 1 illustrates a semiconductor package according to some implementations of the present disclosure.

Referring to FIG. 1, a semiconductor package 1 may include a package substrate SUB, a semiconductor memory device 1000, a host die 2000, and a plurality of through electrodes 300.

The host die 2000 and the semiconductor memory device 1000 may be stacked on the package substrate SUB. The host die 2000 and the semiconductor memory device 1000 may be sequentially stacked along a first direction D1 on an upper surface of the package substrate SUB. The first direction D1 may be perpendicular to the upper surface of the package substrate SUB.

The semiconductor memory device 1000 may include a plurality of semiconductor structures 10, 20,30. Although three semiconductor structures are illustrated, a greater number may be provided. Each of the plurality of semiconductor structures 10, 20, 30 may be stacked in the first direction D1. The semiconductor memory device 1000 may include a high-bandwidth memory (HBM) chip. That is, the semiconductor memory device 1000 may be implemented based on the HBM standard.

The semiconductor memory device 1000 may include a buffer die 10 and core dies 20 and 30. Each core die 20, 30 may include a memory cell array. In some implementations, the semiconductor memory device 1000 may omit the buffer die, and the host die 2000 may additionally serve as the buffer die.

The buffer die 10 may include a physical layer and a direct-access region. The physical layer may be electrically connected to a physical layer of the host die through an interposer. The semiconductor memory device 1000 may receive signals from, or transmit signals to, the host die 2000 through the physical layer.

The buffer die 10 and the core dies 20, 30 may be electrically connected to one another through the plurality of through electrodes 300, first connection pads 310, and second connection pads 320.

The host die 2000 may be mounted on the package substrate SUB through solder bumps. The host die 2000 may execute applications supported by the semiconductor package 1 using the semiconductor memory device 1000. For example, the host die 2000 may include at least one processor selected from among a central processing unit (CPU), an application processor (AP), a graphic processing unit (GPU), a neural processing unit (NPU), a tensor processing unit (TPU), a vision processing unit (VPU), an image signal processor (ISP), and a digital signal processor (DSP) to perform specialized operations.

The host die 2000 may include a physical layer and a memory controller. The physical layer of the host die 2000 may include input/output circuits for transmitting and receiving signals with the physical layer of the semiconductor memory device 1000. The host die 2000 may provide various signals to the physical layer of the semiconductor memory device 1000 through the physical layer. The signals provided to the physical layer of the semiconductor memory device 1000 may be delivered to the core dies through interface circuits of the physical layer of the semiconductor memory device 1000 and the plurality of through electrodes 300.

The semiconductor package described above is merely an example, and other forms of semiconductor packages may be included. For example, the host die 2000 may be implemented as a system-on-chip (SoC) including at least one processor such as a CPU, AP, GPU, or NPU. Alternatively, the host die 2000 and the semiconductor memory device 1000 may be mounted on an interposer that connects the semiconductor memory device and the host die, and the interposer may be mounted on a printed circuit board (PCB).

The semiconductor memory device according to the present disclosure will now be described.

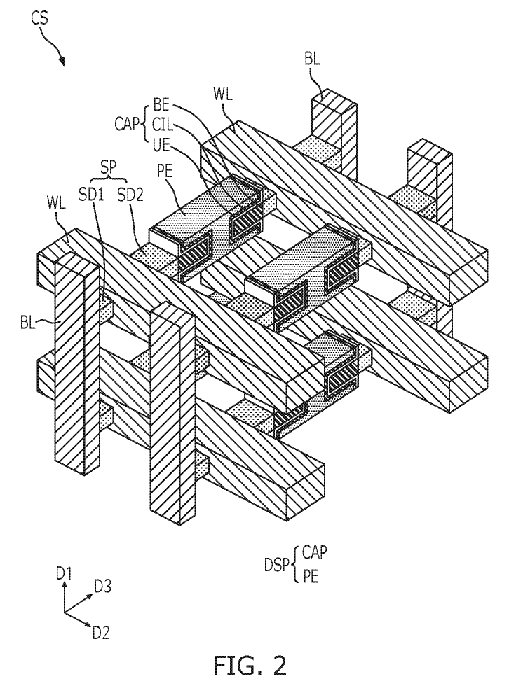

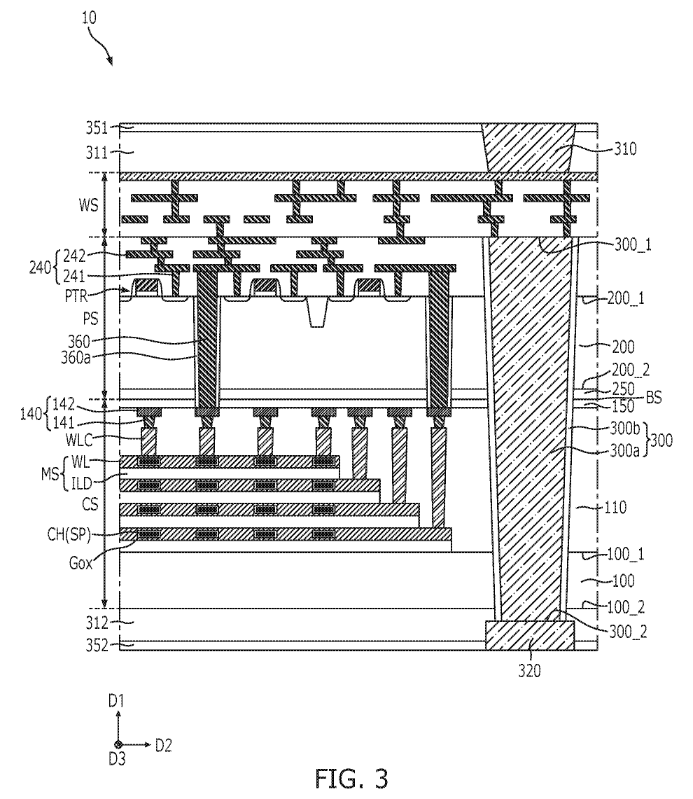

FIG. 2 is a perspective view illustrating some components of a memory cell structure according to some implementations of the present disclosure, and FIG. 3 is a cross-sectional view illustrating a semiconductor structure according to some implementations of the present disclosure.

Referring to FIGS. 2 and 3, the semiconductor memory device according to some implementations of the present disclosure may include a plurality of semiconductor structures 10. The semiconductor memory device may be formed by stacking the plurality of semiconductor structures 10.

Each semiconductor structure 10 may include a memory cell structure CS, a peripheral circuit structure PS, a wiring structure WS, through electrodes 300, through vias 360, and so forth.

The memory cell structure CS may include at least one among various types of memory semiconductors. For example, the memory cell structure CS may include a vertically stacked dynamic random-access memory (VSDRAM), a three-dimensional ferroelectric-field-effect-transistor memory (3D FeFET), or a three-dimensional monolithic memory. In some implementations, the memory cell structure CS may include a two-dimensional memory such as a buried-channel-array-transistor (BCAT) or a vertical-channel-transistor (VCT) dynamic random-access memory.

The peripheral circuit structure PS may be stacked on the memory cell structure CS. That is, the memory cell structure CS and the peripheral circuit structure PS may overlap each other in a first direction D1 perpendicular to the upper surface of the cell substrate 100. The peripheral circuit structure PS may overlap a memory cell array located in the memory cell structure CS in the first direction D1 perpendicular to the upper surface of the cell substrate 100.

The memory cell structure CS may include a cell substrate 100, an interlayer dielectric layer ILD, semiconductor patterns SP, word lines WL, bit lines BL, and data storage patterns DSP. The memory cell structure CS may include a plurality of memory cells stacked on the cell substrate 100 and spaced apart from each other in the first direction D1, and each memory cell may include a semiconductor pattern SP including a channel region CH and a capacitor structure CAP disposed on one side of the semiconductor pattern SP.

The cell substrate 100 may be bulk silicon or silicon on insulator (SOI). Alternatively, the cell substrate 100 may include silicon germanium (SiGe), silicon germanium on insulator (SGOI), indium antimonide, lead telluride compounds, indium arsenide, indium phosphide, gallium arsenide, gallium antimonide, or the like but is not limited thereto.

A first surface 100_1 of the cell substrate 100 may be an upper surface, and a second surface 100_2 may be a lower surface. A direction perpendicular to the first surface 100_1 of the cell substrate 100 is defined as the first direction D1, a direction parallel to the first surface 100_1 and perpendicular to the first direction D1 is defined as a second direction D2. A third direction D3 is a direction perpendicular to both the first and second directions D1 and D2.

A plurality of semiconductor patterns SP may be stacked in the first direction D1. The semiconductor patterns SP may be spaced apart from one another in the second direction D2 and the third direction D3. That is, the semiconductor patterns SP may be arranged three-dimensionally on the cell substrate 100. Each semiconductor pattern SP may include at least one of silicon and germanium. For example, each semiconductor pattern SP may include single-crystal silicon.

Each semiconductor pattern SP may have a bar shape having a long axis in the third direction D3. Each semiconductor pattern SP may include a first source/drain region SD1, a second source/drain region SD2 spaced apart from the first source/drain region SD1, and a channel region CH between the first and second source/drain regions SD1 and SD2. The first source/drain region SD1 may be adjacent to the bit line BL, and the second source/drain region SD2 may be adjacent to the capacitor structure CAP. An impurity may be doped into each of the first and second source/drain regions SD1 and SD2.

Each semiconductor pattern SP may penetrate the word lines WL in the third direction D3. A portion of each semiconductor pattern SP may be surrounded by the word lines WL. Each word line WL may have a gate-all-around structure that completely surrounds the channel region CH of the corresponding semiconductor pattern SP. A gate insulating layer Gox may be interposed between the channel region CH of each semiconductor pattern SP and the word lines WL.

Each of the plurality of word lines WL may extend along the second direction D2. Memory cells arranged along the second direction D2 may be commonly connected to one word line WL. The plurality of word lines WL may be arranged along the first direction D1 or the third direction D3. The plurality of word lines WL may be stacked spaced apart in the first direction D1 on the upper surface of the cell substrate 100.

The plurality of word lines WL may include a conductive material. For example, the conductive material may be a semiconductor material, a conductive metal nitride, a metal, or a metal-semiconductor compound.

An interlayer dielectric layer ILD may be interposed between adjacent ones of the plurality of word lines WL. The plurality of word lines WL and the plurality of interlayer dielectric layers ILD may be alternately stacked. The interlayer dielectric layer ILD may include an insulating material such as silicon oxide, silicon nitride, or silicon oxynitride. Although the interlayer dielectric layer ILD is illustrated as a single layer, it may be a multilayer structure. The plurality of word lines WL and the plurality of interlayer dielectric layers ILD may be alternately stacked to form a stack structure MS. The stack structure MS may have a stepped structure. That is, one ends of the plurality of word lines WL and the plurality of interlayer dielectric layers ILD may have steps.

A cell insulating layer 110 may be disposed on the cell substrate 100 and the stack structure MS. The cell insulating layer 110 may cover both an upper surface of the stack structure MS and side surfaces of the stack structure MS. That is, the cell insulating layer 110 may cover an upper surface of the word line WL positioned at an uppermost level of the stack structure MS and side surfaces of the word lines WL and the interlayer dielectric layers ILD that form the side surfaces of the stack structure MS.

A gate insulating layer Gox may be interposed between each word line WL and each semiconductor pattern SP. The gate insulating layer Gox may surround each channel region CH. Each channel region CH may be spaced apart from a corresponding word line WL by the gate insulating layer Gox. The gate insulating layer Gox may not contact the first and second source/drain regions SD1 and SD2 of each semiconductor pattern SP.

The gate insulating layer Gox may include at least one of a high-dielectric-constant layer, silicon oxide, silicon nitride, and silicon oxynitride. The high-dielectric-constant layer may include, for example, at least one of hafnium oxide, hafnium silicate, lanthanum oxide, zirconium oxide, zirconium silicate, tantalum oxide, titanium oxide, barium-strontium-titanate oxide, barium-titanate oxide, strontium-titanate oxide, lithium oxide, aluminum oxide, lead-scandium-tantalate oxide, and lead-zinc-niobate.

Each of a plurality of bit lines BL may extend in the first direction D1. The bit lines BL may have substantially equal lengths in the first direction D1. The bit lines BL may be arranged spaced apart from one another in the second direction D2 and the third direction D3. Each bit line BL may be connected to the first source/drain region SD1 of each semiconductor pattern SP stacked in the first direction D1.

Each bit line BL may include a conductive material. The conductive material may be, for example, any one of a doped semiconductor material such as doped silicon or doped germanium, a conductive metal nitride such as titanium nitride or tantalum nitride, a metal such as tungsten, titanium, or tantalum, and a metal-semiconductor compound such as tungsten silicide, cobalt silicide, or titanium silicide.

The data storage pattern DSP may include a plurality of capacitor structures CAP and a plate electrode PE. Each capacitor structure CAP may transmit or receive a signal (for example, data) from outside through the plate electrode PE. The data storage pattern DSP may be disposed between a first semiconductor pattern SP1 and a second semiconductor pattern SP2.

Each of the plurality of capacitor structures CAP may include a lower electrode BE, a dielectric layer CIL, and an upper electrode UE. Each capacitor structure CAP may be connected to the second source/drain region SD2 of a corresponding semiconductor pattern SP. The plurality of lower electrodes BE of the capacitor structure CAP may be connected respectively to the second source/drain regions SD2 of the semiconductor patterns SP.

Each lower electrode BE may be disposed on one side surface of the semiconductor pattern SP. For example, the lower electrode BE may include at least one of a metal material such as titanium, tantalum, tungsten, copper, or aluminum, a conductive metal nitride such as titanium nitride, tantalum nitride, or tungsten nitride, and a doped semiconductor material such as doped silicon or doped germanium.

The lower electrodes BE may be provided at substantially the same vertical levels as the semiconductor patterns SP. A thickness of each lower electrode BE may be greater than or equal to a thickness of each semiconductor pattern SP. That is, the lower electrodes BE may be stacked in the first direction D1 and may have long axes in the third direction D3. In some implementations, an interface layer may be interposed between each lower electrode BE and a corresponding semiconductor pattern SP. The interface layer may include, for example, a silicide layer.

The dielectric layer CIL may conformally cover a surface of each lower electrode BE. The dielectric layer CIL may be interposed between each lower electrode BE and a corresponding upper electrode UE. The dielectric layer CIL may include a high-dielectric-constant material. For example, the dielectric layer CIL may include titanium oxide (TiO₂). In some implementations, the dielectric layer CIL may include hafnium oxide, hafnium silicate, lanthanum oxide, zirconium oxide, zirconium silicate, tantalum oxide, barium-strontium-titanate oxide, barium-titanate oxide, strontium-titanate oxide, lithium oxide, aluminum oxide, lead-scandium-tantalate oxide, lead-zinc-niobate, or a combination thereof.

The upper electrode UE may conformally cover a surface of the dielectric layer CIL. The upper electrode UE may be disposed on the dielectric layer CIL. For example, the upper electrode UE may include at least one of titanium, cobalt, nickel, copper, tungsten, niobium, tantalum, manganese, indium, molybdenum, vanadium, hafnium, zirconium, and combinations thereof.

The plate electrode PE may be disposed on the upper electrode UE. The plate electrode PE may fill spaces among the capacitor structures CAP. For example, the plate electrode PE may include impurity-doped silicon or impurity-doped silicon-germanium.

The memory cell structure CS may further include a cell wiring structure 140 and word-line contacts WLC.

The cell wiring structure 140 may include a cell via 141 and a cell wiring layer 142. The number, positions, and/or connection structures of the cell via 141 and the cell wiring layer 142 may be variously modified. The cell wiring structure 140 may include a conductive material. For example, each cell via 141 and each cell wiring layer 142 may include at least one of a metal, a conductive metal nitride, a conductive metal oxide, and a doped semiconductor material.

A word-line contact WLC may be disposed on the word line WL. The word-line contact WLC may extend in the first direction D1. The word-line contact WLC may connect the word line WL to the cell wiring structure 140. For example, a cell via 141 and a cell wiring layer 142 may be sequentially disposed on a word-line contact WLC. The word-line contact WLC may penetrate the cell insulating layer 110 and connect to the word line WL. The word-line contact WLC may be surrounded by the cell insulating layer 110.

The peripheral circuit structure PS may include a peripheral circuit substrate 200, peripheral circuit devices PTR, and a peripheral wiring structure 240.

The peripheral circuit substrate 200 may include a first surface 200_1 and a second surface 200_2 opposite the first surface 200_1. The peripheral circuit structure PS may be disposed such that the second surface 200_2 of the peripheral circuit substrate 200 faces the first surface 100_1 of the cell substrate 100 on the memory cell structure CS.

The peripheral circuit structure PS may be disposed on the memory cell structure CS. In some implementations, the peripheral circuit structure PS and the memory cell structure CS may be bonded by a wafer-to-wafer bonding method. For example, the peripheral circuit structure PS may be bonded on the memory cell structure CS by fusion bonding. A bonding face BS may be formed at an interface between the peripheral circuit structure PS and the memory cell structure CS. Specifically, a cell bonding insulating layer 150 may be disposed on an upper surface of the memory cell structure CS, and a peripheral bonding insulating layer 250 may be disposed on a lower surface of the peripheral circuit structure PS. A contact face between the cell bonding insulating layer 150 and the peripheral bonding insulating layer 250 may be the bonding face BS.

The peripheral circuit devices PTR may be disposed on the first surface 200_1 of the peripheral circuit substrate 200. The peripheral circuit devices PTR may include circuit devices such as transistors. The peripheral circuit devices PTR may configure a circuit that controls memory cells located in the memory cell structure CS. For example, the circuit may include a row decoder that selects a row of a memory cell array based on an address signal, a column decoder that selects a column of the memory cell array based on an address signal, a sense amplifier that detects and amplifies data of memory cells, and a word-line driver that activates a word line of a selected row, but is not limited thereto.

The peripheral wiring structure 240 may include a peripheral via 241 and a peripheral wiring layer 242. The number, positions, and/or connection structures of the peripheral via 241 and the peripheral wiring layer 242 may be variously modified. The peripheral wiring structure 240 may include a conductive material. For example, each peripheral via 241 and each peripheral wiring layer 242 may include at least one of a metal, a conductive metal nitride, a conductive metal oxide, and a doped semiconductor material.

The peripheral circuit structure PS may be electrically connected to the memory cell structure CS so that the peripheral circuit devices PTR control the memory cells of the memory cell structure CS. A through via 360 that electrically connects the peripheral circuit structure PS and the memory cell structure CS may be provided. For example, the through via 360 may electrically connect the peripheral wiring structure 240 to the cell wiring structure 140. The through via 360 may extend in the first direction D1 and may penetrate the peripheral circuit substrate 200, the peripheral bonding insulating layer 250, and the cell bonding insulating layer 150 in the first direction D1. That is, part of the through via 360 may be located in the peripheral circuit structure PS and the remainder may be located in the memory cell structure CS.

The through via 360 may include a conductive material. For example, the through via 360 may include a metal material such as copper, aluminum, or tungsten. A spacer 360a may be provided on a side surface of the through via 360. The spacer 360a may insulate the through via 360 from the peripheral circuit substrate 200 or prevent diffusion of metal atoms. For example, the spacer 360a may include an insulating material such as silicon oxide or silicon nitride.

The wiring structure WS may be disposed on the peripheral circuit structure PS. That is, the memory cell structure CS, the peripheral circuit structure PS, and the wiring structure WS may be sequentially stacked in the first direction D1. The wiring structure WS may be electrically connected to the memory cell structure CS and the peripheral circuit structure PS. The wiring structure WS may include a plurality of wiring vias and a plurality of wiring layers. The number, positions, and/or connection structures of the wiring vias and the wiring layers may be variously modified. In some implementations, the wiring structure WS may be part of the peripheral wiring structure 240. That is, the peripheral wiring structure 240 may include the wiring structure WS.

Each of the plurality of through electrodes 300 may be disposed in the semiconductor structure 10. Each through electrode 300 may connect the wiring structure WS to the second connection pad 320. Each through electrode 300 may extend in the first direction D1 in the semiconductor structure 10. Each through electrode 300 may penetrate at least part of the semiconductor structure 10 in the first direction D1. For example, each through electrode 300 may penetrate the memory cell structure CS and the peripheral circuit structure PS in the first direction D1. Each through electrode 300 may overlap the memory cell structure CS and the peripheral circuit structure PS in the second direction D2 or the third direction D3. The through electrode 300 may be a through-silicon via TSV.

The through electrode 300 may include a conductive film 300a and a barrier film surrounding the conductive film 300a. The conductive film 300a may include a conductive material such as copper, aluminum, or tungsten. The barrier film may include a conductive material having barrier properties such as titanium, titanium nitride, tantalum, tantalum nitride, ruthenium, cobalt, manganese, or tungsten nitride. The barrier film may prevent diffusion of metal atoms of the conductive film 300a. In some implementations, an insulating film 300b may surround a sidewall of the through electrode 300.

The through electrode 300 may include a first surface 300_1 and a second surface 300_2. The first surface 300_1 is defined as a surface that contacts the wiring structure WS, and the second surface 300_2 is defined as a surface opposite the first surface 300_1. A width of the through electrode 300 may decrease from the first surface 300_1 toward the second surface 300_2 along the first direction D1.

The first surface 300_1 of the through electrode 300 may be coplanar with an upper surface of the peripheral circuit structure PS. That is, the first surface 300_1 of the through electrode 300 may be coplanar with an interface between the peripheral circuit structure PS and the wiring structure WS.

On the wiring structure WS, a first interlayer dielectric layer 311, a first bonding insulating layer 351, and the first connection pad 310 may be disposed. The first connection pad 310 may be formed after removing parts of the first interlayer dielectric layer 311 and the first bonding insulating layer 351. The first connection pad 310 may overlap the first interlayer dielectric layer 311 and the first bonding insulating layer 351 in the second direction D2 or the third direction D3. An upper surface of the first connection pad 310 may be coplanar with an upper surface of the first bonding insulating layer 351. That is, the upper surface of the first connection pad 310 and the upper surface of the first bonding insulating layer 351 may form an upper surface of the semiconductor structure 10. Although the first interlayer dielectric layer 311 and the first bonding insulating layer 351 are illustrated as separate layers, they may be a single layer or a multilayer. Each of the first interlayer dielectric layer 311 and the first bonding insulating layer 351 may include an insulating material such as silicon oxide or silicon nitride.

In some implementations, the first connection pad 310 may have a width that decreases with a decrease in distance to the wiring structure WS along the first direction D1. However, a shape of the first connection pad 310 is not limited thereto and may have a width that increases with a decrease in distance to the wiring structure WS along the first direction D1.

A second interlayer dielectric layer 312 and a second bonding insulating layer 352 may be sequentially disposed on the second surface 100_2 of the cell substrate 100. The second connection pad 320 may be formed after removing parts of the second interlayer dielectric layer 312 and the second bonding insulating layer 352. The second connection pad 320 may overlap the second interlayer dielectric layer 312 and the second bonding insulating layer 352 in the second direction D2 or the third direction D3. A lower surface of the second connection pad 320 may be coplanar with a lower surface of the second bonding insulating layer 352. That is, the lower surface of the second connection pad 320 and the lower surface of the second bonding insulating layer 352 may form a lower surface of the semiconductor structure 10. Although the second interlayer dielectric layer 312 and the second bonding insulating layer 352 are illustrated as separate layers, they may be a single layer or a multilayer. Each of the second interlayer dielectric layer 312 and the second bonding insulating layer 352 may include an insulating material such as silicon oxide or silicon nitride.

In some implementations, the second connection pad 320 may have a width that decreases with a decrease in distance to the through electrode 300 along the first direction D1. However, a shape of the second connection pad 320 is not limited thereto and may have a width that increases with a decrease in distance to the through electrode 300 along the first direction D1.

Each of the first connection pad 310 and the second connection pad 320 may include a conductive material such as copper. Thus, an upper surface of the semiconductor structure 10 may be composed of the first bonding insulating layer 351 including an insulating material and the first connection pad 310 including copper. A lower surface of the semiconductor structure 10 may be composed of the second bonding insulating layer 352 including an insulating material and the second connection pad 320 including copper.

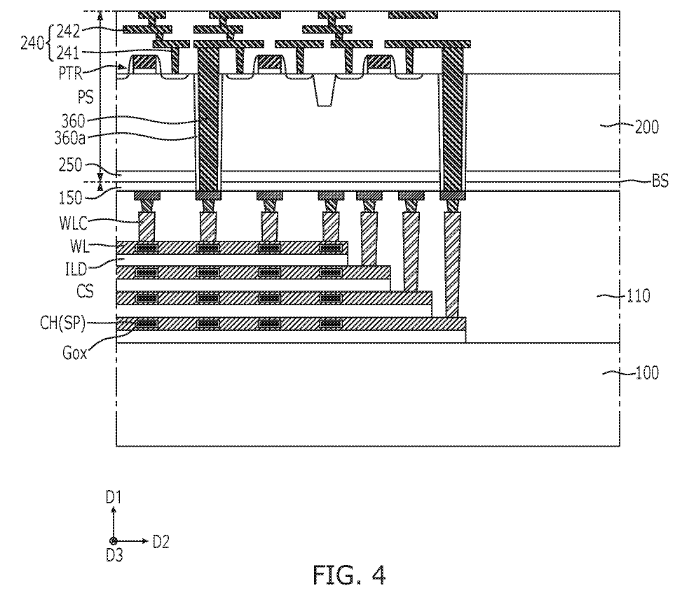

FIGS. 4-8 are cross-sectional views illustrating a method of manufacturing a semiconductor structure according to some implementations of the present disclosure.

Referring to FIG. 4, the peripheral circuit structure PS may be stacked on the memory cell structure CS. For example, the cell bonding insulating layer 150 may be formed on an upper surface of the memory cell structure CS, and the peripheral bonding insulating layer 250 may be formed on a lower surface of the peripheral circuit structure PS. Next, the cell bonding insulating layer 150 and the peripheral bonding insulating layer 250 may be stacked so that they face each other. In a state in which the cell bonding insulating layer 150 contacts the peripheral bonding insulating layer 250, a bonding face BS may be formed by bonding the cell bonding insulating layer 150 to the peripheral bonding insulating layer 250 through plasma activation and/or annealing.

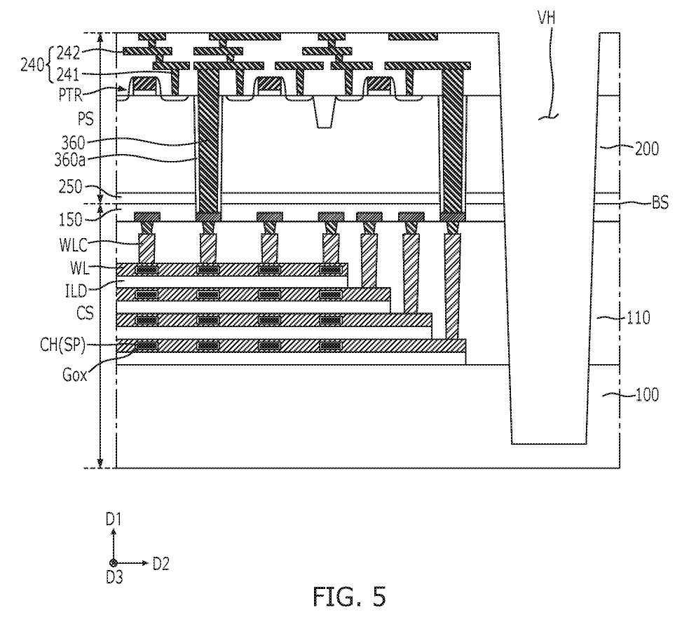

Referring to FIG. 5, parts of the memory cell structure CS and the peripheral circuit structure PS may be removed to form a via hole VH. Parts of the memory cell structure CS and the peripheral circuit structure PS may be penetrated in the first direction D1 to a predetermined depth. For example, the peripheral circuit structure PS may be penetrated, and a portion from an upper surface of the memory cell structure CS to part of the cell substrate 100 may be penetrated. Specifically, the upper surface of the cell substrate 100 may be penetrated, but the lower surface of the cell substrate 100 may not be penetrated.

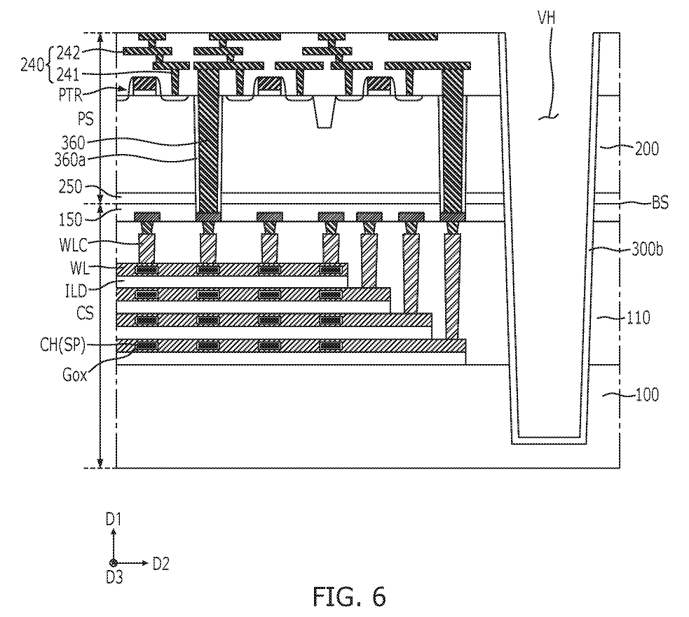

Referring to FIG. 6, an insulating film 300b may be formed in the via hole VH. The insulating film 300b may include an insulating material including at least one of silicon oxide, silicon nitride, and silicon oxynitride. For example, the insulating film 300b may be formed by a chemical-vapor-deposition (CVD) method but is not limited thereto.

Next, a barrier film may be formed on the insulating film 300b. The barrier film may be formed in the via hole VH. The barrier film may include a conductive material having barrier characteristics such as titanium, titanium nitride, tantalum, tantalum nitride, ruthenium, cobalt, manganese, or tungsten nitride. For example, the barrier film may be formed by a physical-vapor-deposition (PVD), chemical-vapor-deposition (CVD), or atomic-layer-deposition (ALD) method.

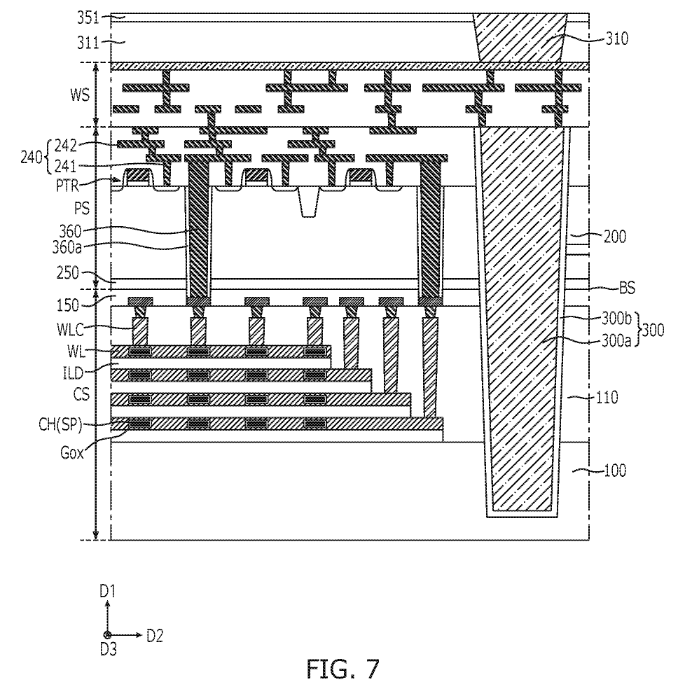

Referring to FIG. 7, a conductive material may fill the via hole VH to form the conductive film 300a. The conductive film 300a may be formed by a plating process in which a seed layer is formed on the barrier film (or the insulating film 300b) and a conductive material grows from the seed layer. For example, the conductive film 300a may include copper. In some implementations, the insulating film 300b, the barrier film, and/or the conductive film 300a may also be formed on an upper surface of the peripheral circuit structure PS. In that case, a planarization process may be performed.

In this manner, the through electrode 300 may be formed. The first surface 300_1 of the through electrode 300 may be coplanar with an upper surface of the peripheral circuit structure PS. The wiring structure WS may be formed on the upper surface of the peripheral circuit structure PS and the first surface 300_1 of the through electrode 300. The wiring structure WS may be electrically connected to the peripheral wiring structure 240 and the through electrode 300.

Next, the first interlayer dielectric layer 311 and the first bonding insulating layer 351 may be sequentially formed on the wiring structure WS. After parts of the first interlayer dielectric layer 311 and the first bonding insulating layer 351 are removed, the first connection pad 310 may be formed. For example, an etching process may remove parts of the first interlayer dielectric layer 311 and the first bonding insulating layer 351, and a conductive material such as copper may fill the removed region to form the first connection pad 310. The first connection pad 310 may be positioned to overlap the through electrode 300 in the first direction D1. In some implementations, the wiring structure WS may be omitted, and the first connection pad 310 may be disposed on the through electrode 300.

Through the etching process, the first interlayer dielectric layer 311 and the first bonding insulating layer 351 may gradually decrease in width with a decrease in distance to the wiring structure WS. Thus the first connection pad 310 may have a width that decreases with a decrease in distance to the wiring structure WS. In some implementations, through a planarization process, an upper surface of the first connection pad 310 may be coplanar with an upper surface of the first bonding insulating layer 351. In some implementations, dishing may occur at the upper surface of the first connection pad 310.

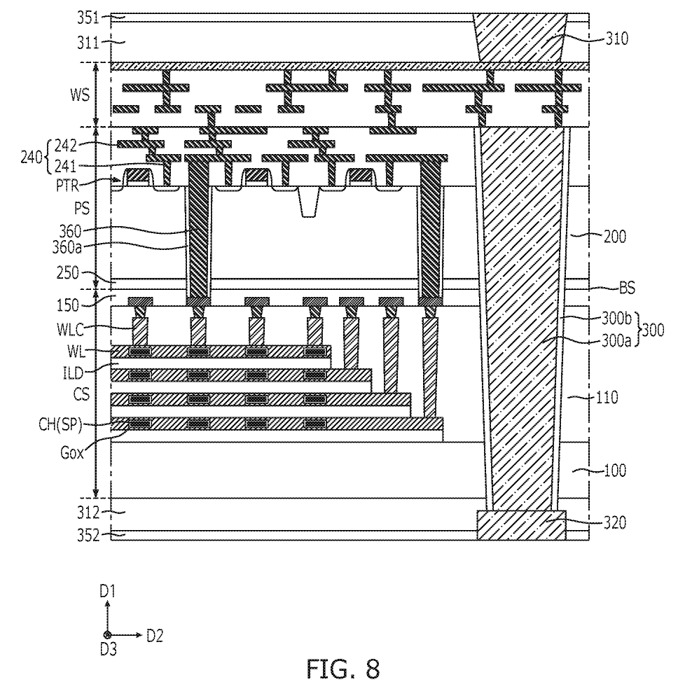

Referring to FIG. 8, part of the cell substrate 100 may be removed. In some implementations, part of the through electrode 300 may be removed together. For example, the insulating film 300b located on a lower surface of the conductive film 300a may be removed. A planarization process may be performed with respect to the cell substrate 100 and/or the through electrode 300. A second interlayer dielectric layer 312 and a second bonding insulating layer 352 may be sequentially formed in a region from which the cell substrate 100 and/or the through electrode 300 has been removed.

Next, after parts of the second interlayer dielectric layer 312 and the second bonding insulating layer 352 are removed, the second connection pad 320 may be formed. For example, an etching process may remove parts of the second interlayer dielectric layer 312 and the second bonding insulating layer 352, and a conductive material such as copper may fill the removed region to form the second connection pad 320. In some implementations, through a planarization process, a lower surface of the second connection pad 320 may be coplanar with a lower surface of the second bonding insulating layer 352.

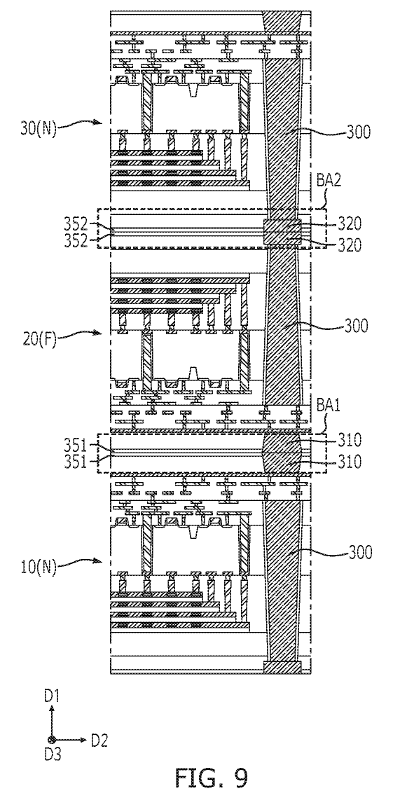

FIGS. 9-12 are diagrams illustrating a semiconductor memory device in which the semiconductor structure of FIG. 3 is stacked.

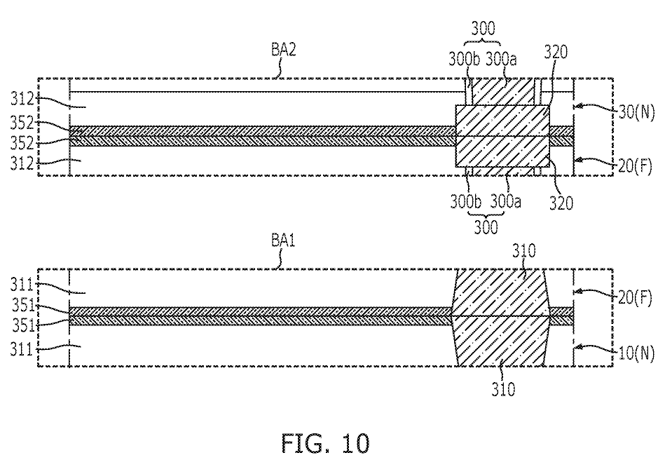

Referring to FIGS. 9 and 10, a plurality of semiconductor structures 10, 20, and 30 may be sequentially stacked along a first direction D1. For example, the second semiconductor structure 20 may be disposed on the first semiconductor structure 10, and the third semiconductor structure 30 may be disposed on the second semiconductor structure 20.

The plurality of semiconductor structures 10, 20, and 30 may have identical structures. Each of the plurality of semiconductor structures 10, 20, and 30 may include a through electrode 300. A through electrode located in the first semiconductor structure 10 is referred to as a first through electrode, a through electrode located in the second semiconductor structure 20 is referred to as a second through electrode, and a through electrode located in the third semiconductor structure 30 is referred to as a third through electrode. In addition, the memory cell structure and the peripheral circuit structure may be referred to as first to third memory cell structures and first to third peripheral circuit structures, respectively.

Each of the plurality of through electrodes 300 may be aligned in the first direction D1. For example, the first through electrode, the second through electrode, and the third through electrode may be aligned with one another in the first direction D1. The plurality of semiconductor structures 10, 20, and 30 may have a PoC (Peri on Cell) structure in which the peripheral circuit structure is disposed on an upper side of the memory cell structure. The first semiconductor structure 10 may be placed in a normal state N, the second semiconductor structure 20 may be stacked on the first semiconductor structure 10 in a flipped state F, and the third semiconductor structure 30 may be stacked on the second semiconductor structure 20 in the normal state N. That is, a front surface of the first semiconductor structure 10 may be bonded to a front surface of the second semiconductor structure 20, and a rear surface of the second semiconductor structure 20 may be bonded to a rear surface of the third semiconductor structure 30. For example, the plurality of semiconductor structures 10, 20, and 30 may be bonded to one another by a hybrid copper bonding (HCB) method.

In a first bonding region BA1 between the first semiconductor structure 10 and the second semiconductor structure 20, a first connection pad 310 and a first bonding insulating layer 351 may be bonded to each other. The first connection pad 310 (also referred to as “a first front-side connection pad”) of the first semiconductor structure 10 may contact the first connection pad 310 (also referred to as “a second front-side connection pad”) of the second semiconductor structure 20, and the first bonding insulating layer 351 of the first semiconductor structure 10 may contact the first bonding insulating layer 351 (also referred to as “a front-side bonding insulating layer”) of the second semiconductor structure 20. In some implementations, the first connection pad 310 of the first semiconductor structure 10 may partially contact the first bonding insulating layer 351 of the second semiconductor structure 20.

In a second bonding region BA2 between the second semiconductor structure 20 and the third semiconductor structure 30, respective second connection pads 320 and respective second bonding insulating layers 352 of the second semiconductor structure 20 and the third semiconductor structure 30 may be bonded to each other. The second connection pad 320 of the second semiconductor structure 20 may contact the second connection pad 320 of the third semiconductor structure 30, and the second bonding insulating layer 352 of the second semiconductor structure 20 may contact the second bonding insulating layer 352 of the third semiconductor structure 30. In some implementations, the second connection pad 320 of the second semiconductor structure 20 may partially contact the second bonding insulating layer 352 of the third semiconductor structure 30.

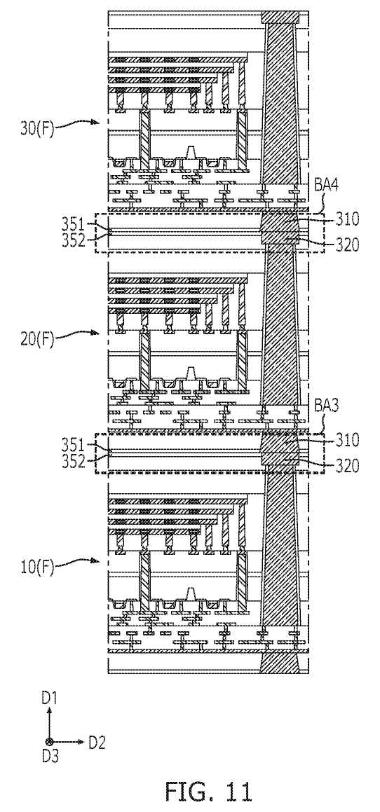

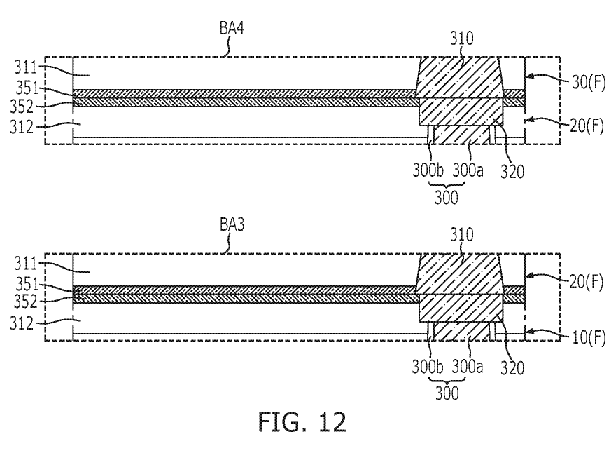

Referring to FIGS. 11 and 12, the plurality of semiconductor structures 10, 20, and 30 may be sequentially stacked along the first direction D1. For example, the second semiconductor structure 20 may be disposed on the first semiconductor structure 10, and the third semiconductor structure 30 may be disposed on the second semiconductor structure 20.

The plurality of semiconductor structures 10, 20, and 30 may have identical structures. The plurality of semiconductor structures 10, 20, and 30 may have a PoC structure in which the peripheral circuit structure is disposed on an upper side of the memory cell structure. Each of the first semiconductor structure 10, the second semiconductor structure 20, and the third semiconductor structure 30 may be sequentially stacked in the flipped state F. That is, a rear surface of the first semiconductor structure 10 may be bonded to a front surface of the second semiconductor structure 20, and a rear surface of the second semiconductor structure 20 may be bonded to a front surface of the third semiconductor structure 30.

For example, the plurality of semiconductor structures 10, 20, and 30 may be bonded to one another by the HCB method. In a third bonding region BA3 between the first semiconductor structure 10 and the second semiconductor structure 20, a second connection pad 320 (also referred to as “a first back-side connection pad 320”) of the first semiconductor structure 10 may be bonded to a first connection pad 310 (also referred to as “a second front-side connection pad 310”) of the second semiconductor structure 20, and a second bonding insulating layer 352 of the first semiconductor structure 10 may be bonded to a first bonding insulating layer 351 of the second semiconductor structure 20. The second connection pad 320 of the first semiconductor structure 10 may contact the first connection pad 310 of the second semiconductor structure 20, and the second bonding insulating layer 352 of the first semiconductor structure 10 may contact the first bonding insulating layer 351 of the second semiconductor structure 20. In some implementations, the first connection pad 310 of the second semiconductor structure 20 may partially contact the second bonding insulating layer 352 of the first semiconductor structure 10.

In a fourth bonding region BA4 between the second semiconductor structure 20 and the third semiconductor structure 30, a second connection pad 320 of the second semiconductor structure 20 may be bonded to a first connection pad 310 of the third semiconductor structure 30, and a second bonding insulating layer 352 of the second semiconductor structure 20 may be bonded to a first bonding insulating layer 351 of the third semiconductor structure 30. The second connection pad 320 of the second semiconductor structure 20 may contact the first connection pad 310 of the third semiconductor structure 30, and the second bonding insulating layer 352 of the second semiconductor structure 20 may contact the first bonding insulating layer 351 of the third semiconductor structure 30. In some implementations, the first connection pad 310 of the third semiconductor structure 30 may partially contact the second bonding insulating layer 352 of the second semiconductor structure 20.

Hereinafter, implementations different from the implementations described above will be explained. The same reference numerals are assigned to identical elements, and detailed descriptions thereof are omitted.

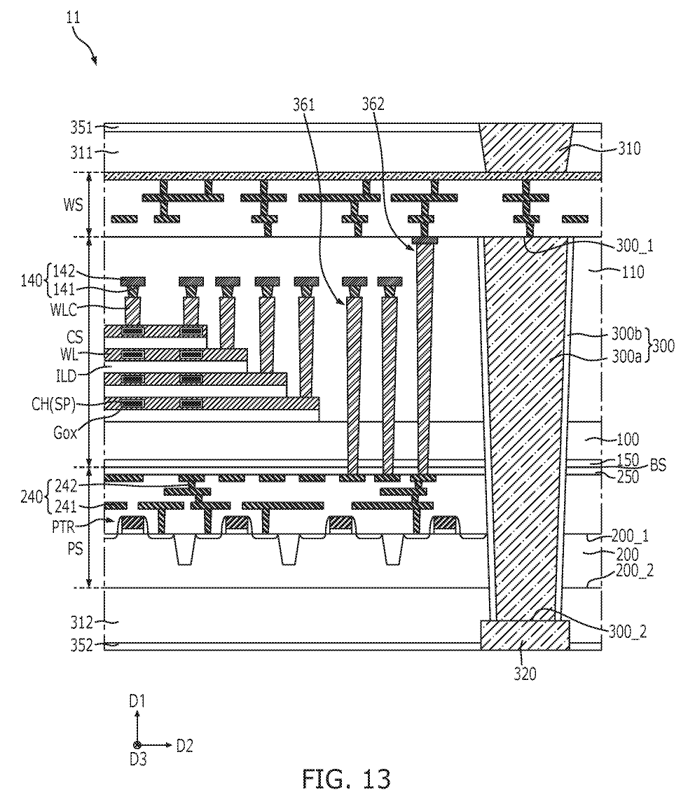

FIG. 13 is a cross-sectional view illustrating a semiconductor structure according to some implementations of the present disclosure.

Referring to FIG. 13, a semiconductor structure 10A according to some implementations of the present disclosure may differ from the implementation of FIG. 3 in an arrangement of a memory cell structure CS and a peripheral circuit structure PS.

A memory cell structure CS and a wiring structure WS may be sequentially stacked on the peripheral circuit structure PS. That is, the memory cell structure CS may be disposed on the peripheral circuit structure PS, and the wiring structure WS may be disposed on the memory cell structure CS. In some implementations, the peripheral circuit structure PS and the memory cell structure CS may be joined by a wafer-to-wafer bonding method. For example, the peripheral circuit structure PS may be bonded on the memory cell structure CS by fusion bonding. A bonding face BS may be formed at an interface between the peripheral circuit structure PS and the memory cell structure CS. Specifically, a cell bonding insulating layer 150 may be disposed on an upper surface of the peripheral circuit structure PS, and a peripheral bonding insulating layer 250 may be disposed on a lower surface of the memory cell structure CS. A contact face between the cell bonding insulating layer 150 and the peripheral bonding insulating layer 250 may be the bonding face BS.

The memory cell structure CS may further include a first through via 361 and a second through via 362.

The first through via 361 may electrically connect the peripheral circuit structure PS to the memory cell structure CS. The first through via 361 may extend in the first direction D1 and may penetrate parts of the memory cell structure CS and the peripheral circuit structure PS in the first direction D1. For example, the first through via 361 may penetrate the cell insulating layer 110, the cell substrate 100, the cell bonding insulating layer 150, and the peripheral bonding insulating layer 250 in the first direction D1. The first through via 361 may connect the cell wiring structure 140 to the peripheral wiring structure 240.

The second through via 362 may electrically connect the peripheral circuit structure PS to the wiring structure WS. The second through via 362 may extend in the first direction D1 and may penetrate parts of the memory cell structure CS and the peripheral circuit structure PS in the first direction D1. For example, the second through via 362 may penetrate the cell insulating layer 110, the cell substrate 100, the cell bonding insulating layer 150, and the peripheral bonding insulating layer 250 in the first direction D1. The second through via 362 may connect the wiring structure WS to the peripheral wiring layer 240.

A first surface 300_1 of a through electrode 300 may be coplanar with an upper surface of the memory cell structure CS. That is, the first surface 300_1 of the through electrode 300 may be coplanar with an interface between the memory cell structure CS and the wiring structure WS.

A distance between the interface of the memory cell structure CS and the wiring structure WS and a second surface 300_2 of the through electrode 300 may be greater than a distance from the same interface to a second surface 200_2 (that is, a lower surface) of the peripheral circuit substrate 200. That is, the second surface 300_2 of the through electrode 300 may be located at a level lower than the peripheral circuit substrate 200.

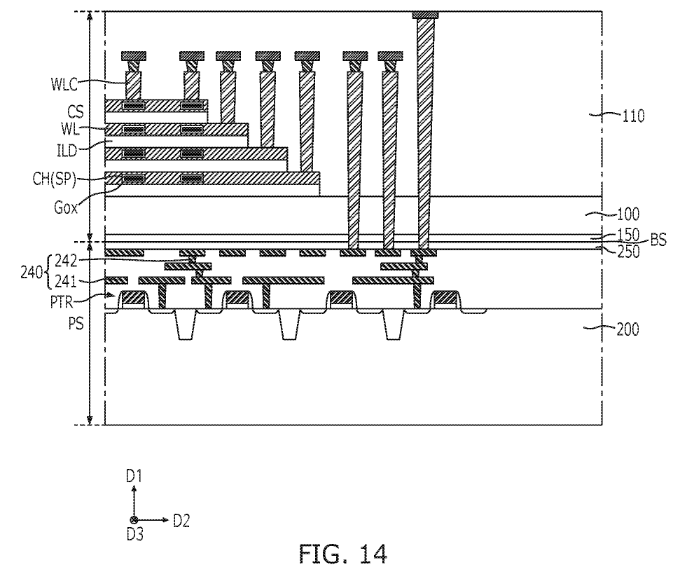

FIGS. 14-17 are cross-sectional views illustrating a method of manufacturing a semiconductor structure according to some implementations of the present disclosure.

Referring to FIG. 14, the memory cell structure CS may be stacked on the peripheral circuit structure PS. For example, the cell bonding insulating layer 150 may be formed on a lower surface of the memory cell structure CS, and the peripheral bonding insulating layer 250 may be formed on an upper surface of the peripheral circuit structure PS. Next, the cell bonding insulating layer 150 and the peripheral bonding insulating layer 250 may be stacked so that they face each other. In a state in which the cell bonding insulating layer 150 contacts the peripheral bonding insulating layer 250, the bonding face BS may be formed by bonding the cell bonding insulating layer 150 to the peripheral bonding insulating layer 250 through plasma activation and/or annealing.

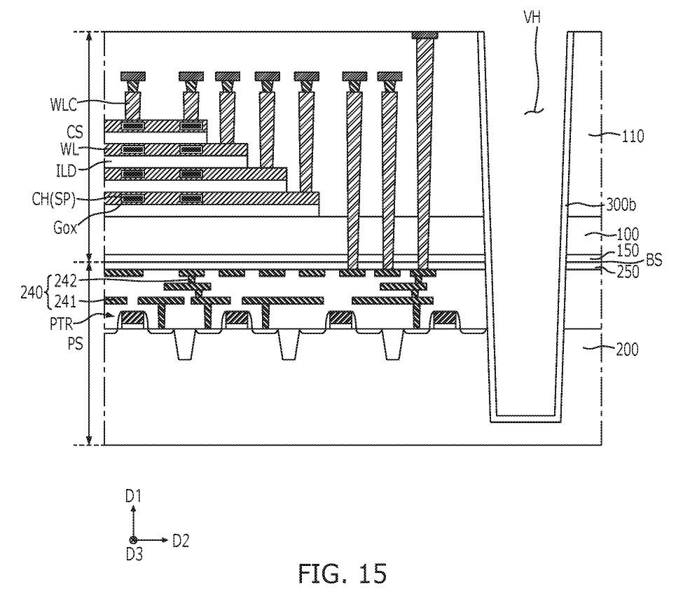

Referring to FIG. 15, parts of the memory cell structure CS and the peripheral circuit structure PS may be removed to form a via hole VH. The via hole VH may penetrate parts of the memory cell structure CS and the peripheral circuit structure PS in the first direction D1 to a predetermined depth. For example, the memory cell structure CS may be penetrated, and a portion from an upper surface of the peripheral circuit structure PS to part of the peripheral circuit substrate 200 may be penetrated. Specifically, the upper surface of the peripheral circuit substrate 200 may be penetrated, but the lower surface thereof may not be penetrated.

An insulating film 300b may be formed in the via hole VH. The insulating film 300b may include an insulating material including at least one of silicon oxide, silicon nitride, and silicon oxynitride. For example, the insulating film 300b may be formed by a CVD method but is not limited thereto.

Next, a barrier film may be formed on the insulating film 300b in the via hole VH. The barrier film may include a conductive material having barrier characteristics, such as titanium, titanium nitride, tantalum, tantalum nitride, ruthenium, cobalt, manganese, or tungsten nitride, and may be formed by PVD, CVD, or ALD.

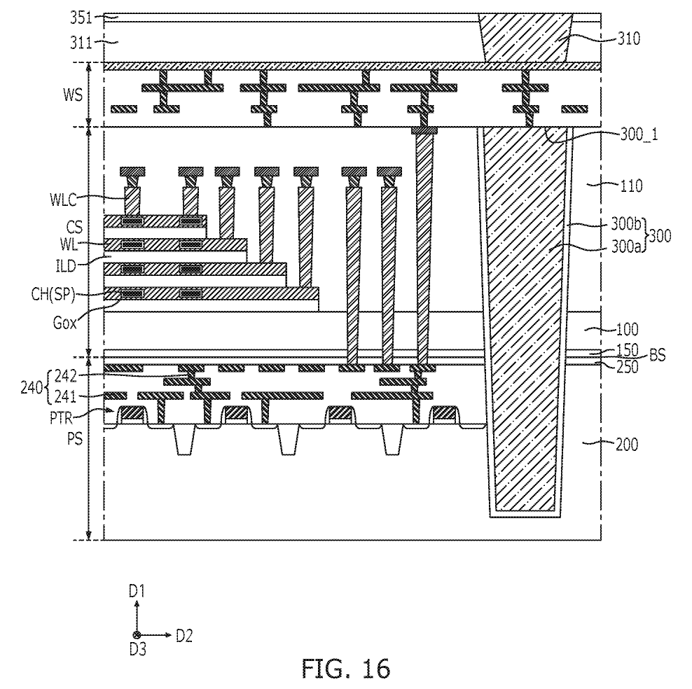

Referring to FIG. 16, the via hole may be filled with a conductive material to form a conductive film 300a. The conductive film 300a may be formed by a plating process in which a seed layer is formed on the barrier film and a conductive material grows from the seed layer. For example, the conductive film 300a may include copper. In some implementations, the insulating film 300b, the barrier film, and/or the conductive film 300a may also be formed on an upper surface of the peripheral circuit structure PS, and a planarization process may then be performed.

Thus, the through electrode 300 may be formed. The first surface 300_1 of the through electrode 300 may be coplanar with an upper surface of the peripheral circuit structure PS. The wiring structure WS may be formed on the upper surfaces of the peripheral circuit structure PS and the first surface 300_1 of the through electrode 300. The wiring structure WS may be electrically connected to the peripheral wiring structure 240 and the through electrode 300.

Next, a first interlayer dielectric layer 311 and a first bonding insulating layer 351 may be sequentially formed on the wiring structure WS. After parts of the first interlayer dielectric layer 311 and the first bonding insulating layer 351 are removed, a first connection pad 310 may be formed by filling a conductive material such as copper. Through the etching process, the first interlayer dielectric layer 311 and the first bonding insulating layer 351 may gradually decrease in width with a decrease in distance to the wiring structure WS, and therefore the first connection pad 310 may have a width that decreases with a decrease in distance to the wiring structure WS. In some implementations, a planarization process may render an upper surface of the first connection pad 310 coplanar with an upper surface of the first bonding insulating layer 351. In some implementations, dishing may occur on the upper surface of the first connection pad 310.

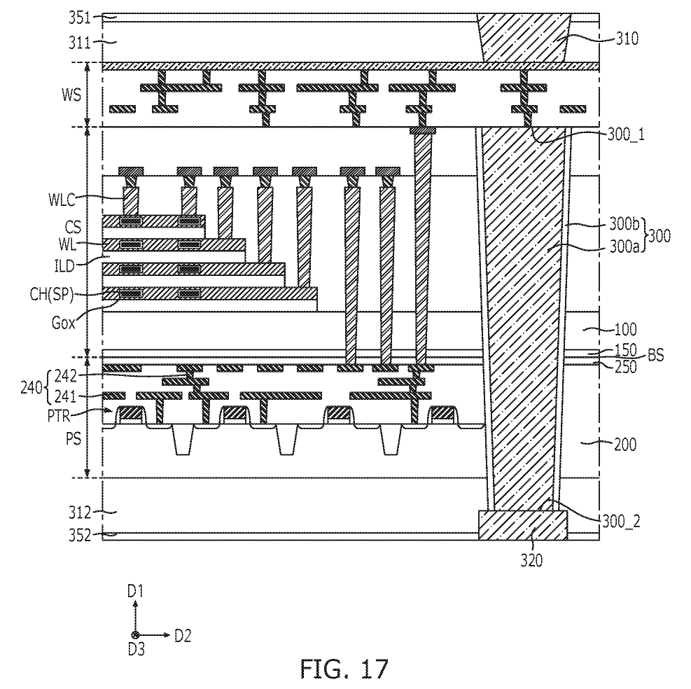

Referring to FIG. 17, part of the peripheral circuit substrate 200 may be removed, and a planarization process may be performed with respect to the peripheral circuit substrate 200 and/or the through electrode 300. A second interlayer dielectric layer 312 and a second bonding insulating layer 352 may be sequentially formed in a region from which the peripheral circuit substrate 200 and/or the through electrode 300 has been removed.

Next, after parts of the second interlayer dielectric layer 312 and the second bonding insulating layer 352 are removed, a second connection pad 320 may be formed by filling a conductive material such as copper. In some implementations, a planarization process may render a lower surface of the second connection pad 320 coplanar with a lower surface of the second bonding insulating layer 352.

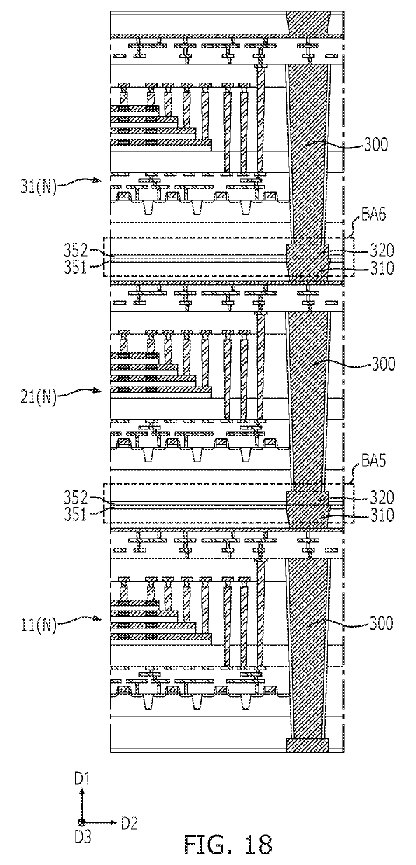

FIGS. 18-21 are diagrams illustrating a semiconductor memory device in which the semiconductor structure of FIG. 13 is stacked.

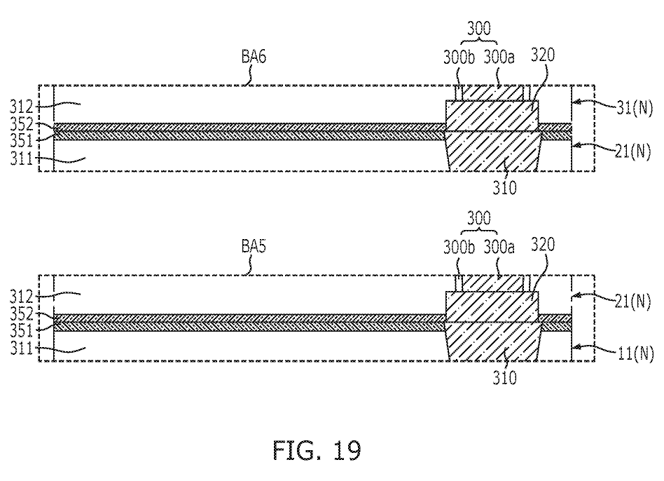

Referring to FIGS. 18 and 19, semiconductor structures 11, 21, and 31 may be sequentially stacked along the first direction D1. For example, the second semiconductor structure 21 may be disposed on the first semiconductor structure 11, and the third semiconductor structure 31 may be disposed on the second semiconductor structure 21.

The plurality of semiconductor structures 11, 21, and 31 may have identical structures. The plurality of semiconductor structures 11, 21, and 31 may have a CoP (Cell on Peri) structure in which the memory cell structure is disposed on an upper side of the peripheral circuit structure. The first semiconductor structure 11, the second semiconductor structure 21, and the third semiconductor structure 31 may each be stacked in the normal state N. That is, a front surface of the first semiconductor structure 11 may be bonded to a rear surface of the second semiconductor structure 21, and a front surface of the second semiconductor structure 21 may be bonded to a rear surface of the third semiconductor structure 31. For example, the plurality of semiconductor structures 11, 21, and 31 may be bonded to one another by the HCB method.

In a fifth bonding region BA5 between the first semiconductor structure 11 and the second semiconductor structure 21, a first connection pad 310 of the first semiconductor structure 11 may be bonded to a second connection pad 320 of the second semiconductor structure 21, and a first bonding insulating layer 351 of the first semiconductor structure 11 may be bonded to a second bonding insulating layer 352 of the second semiconductor structure 21. The first connection pad 310 of the first semiconductor structure 11 may contact the second connection pad 320 of the second semiconductor structure 21. The first bonding insulating layer 351 of the first semiconductor structure 11 may contact the second bonding insulating layer 352 of the second semiconductor structure 21. In some implementations, the first connection pad 310 of the first semiconductor structure 11 may partially contact the second bonding insulating layer 352 of the second semiconductor structure 21.

In a sixth bonding region BA6 between the second semiconductor structure 21 and the third semiconductor structure 31, a first connection pad 310 of the second semiconductor structure 21 may be bonded to a second connection pad 320 of the third semiconductor structure 31, and a first bonding insulating layer 351 of the second semiconductor structure 21 may be bonded to a second bonding insulating layer 352 of the third semiconductor structure 31.

The first connection pad 310 of the second semiconductor structure 21 may contact the second connection pad 320 of the third semiconductor structure 31. The first bonding insulating layer 351 of the second semiconductor structure 21 may contact the second bonding insulating layer 352 of the third semiconductor structure 31. In some implementations, the first connection pad 310 of the second semiconductor structure 21 may partially contact the second bonding insulating layer 352 of the third semiconductor structure 31.

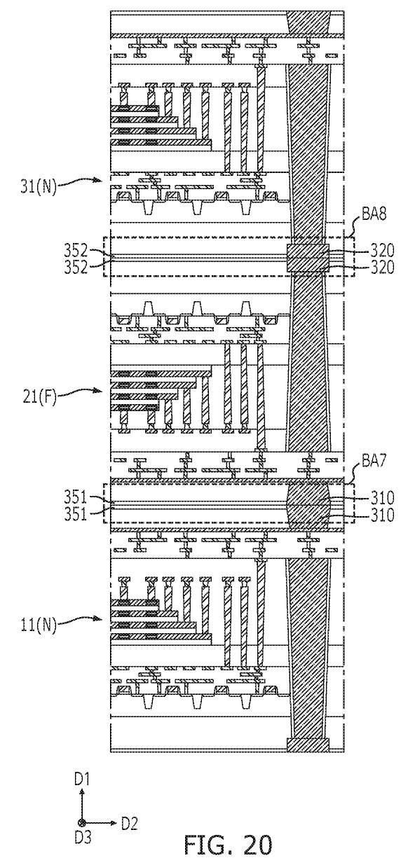

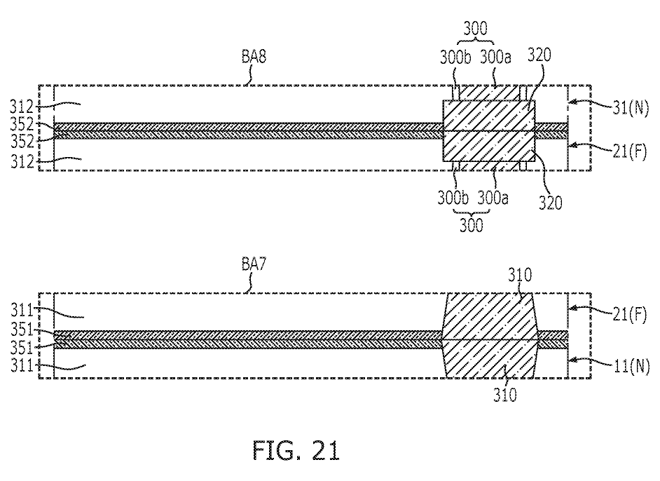

Referring to FIGS. 20 and 21, the first semiconductor structure 11 may be placed in the normal state N, the second semiconductor structure 21 may be stacked on the first semiconductor structure 11 in the flipped state F, and the third semiconductor structure 31 may be stacked on the second semiconductor structure 21 in the normal state N. That is, the first semiconductor structure 11 and the second semiconductor structure 21 may be bonded front-to-front, and the second semiconductor structure 21 and the third semiconductor structure 31 may be bonded rear-to-rear.

For example, the plurality of semiconductor structures 11, 21, and 31 may be bonded to one another by the HCB method. In a seventh bonding region BA7 between the first semiconductor structure 11 and the second semiconductor structure 21, respective first connection pads 310 and respective first bonding insulating layers 351 of the first semiconductor structure 11 and the second semiconductor structure 21 may be bonded to each other. The first connection pad 310 of the first semiconductor structure 11 may contact the first connection pad 310 of the second semiconductor structure 21. The first bonding insulating layer 351 of the first semiconductor structure 11 may contact the first bonding insulating layer 351 of the second semiconductor structure 21. In some implementations, the first connection pad 310 of the first semiconductor structure 11 may partially contact the first bonding insulating layer 351 of the second semiconductor structure 21.

In an eighth bonding region BA8 between the second semiconductor structure 21 and the third semiconductor structure 31, respective second connection pads 320 and respective second bonding insulating layers 352 of the second semiconductor structure 21 and the third semiconductor structure 31 may be bonded to each other. The second connection pad 320 of the second semiconductor structure 21 may contact the second connection pad 320 of the third semiconductor structure 31. The second bonding insulating layer 352 of the second semiconductor structure 21 may contact the second bonding insulating layer 352 of the third semiconductor structure 31. In some implementations, the second connection pad 320 of the second semiconductor structure 21 may partially contact the second bonding insulating layer 352 of the third semiconductor structure 31.

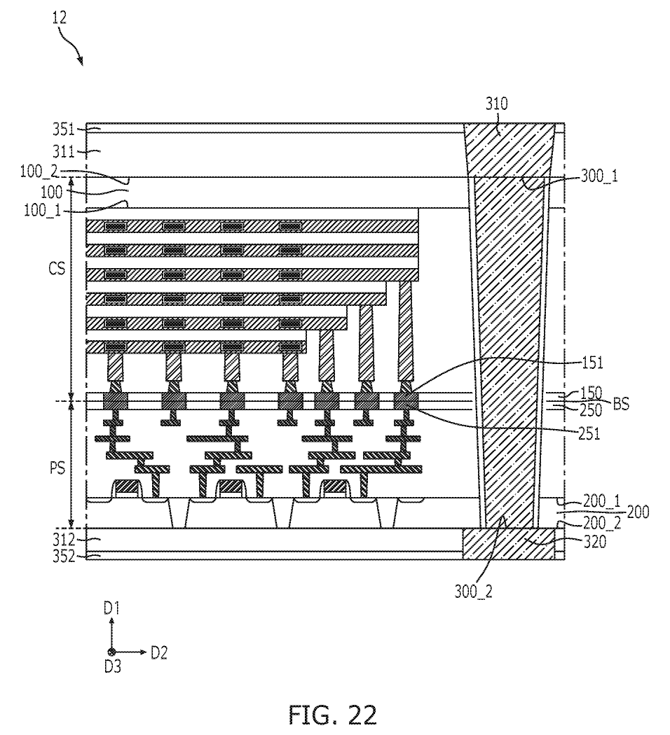

FIGS. 22-24 are diagrams illustrating a semiconductor structure and a semiconductor memory device according to some implementations of the present disclosure.

Referring to FIGS. 22-24, a bonding scheme between a memory cell structure CS and a peripheral circuit structure PS may differ from that of the implementation of FIG. 3. A semiconductor structure 12 may have a CoP structure in which the memory cell structure CS is disposed on an upper side of the peripheral circuit structure PS.

The memory cell structure CS may be disposed on the peripheral circuit structure PS such that a first surface 100_1 of the cell substrate 100 faces a first surface 200_1 of the peripheral circuit substrate 200. In some implementations, the peripheral circuit structure PS and the memory cell structure CS may be joined by a wafer-to-wafer bonding method. For example, the memory cell structure CS may be bonded on the peripheral circuit structure PS by the HCB method. A bonding face BS may be formed at an interface between the peripheral circuit structure PS and the memory cell structure CS. In some implementations, a wiring structure may be disposed between the memory cell structure CS and the peripheral circuit structure PS.

A cell bonding insulating layer 150 may be disposed on a lower surface of the memory cell structure CS. A peripheral bonding insulating layer 250 may be disposed on an upper surface of the peripheral circuit structure PS. A cell bonding pad 151 may be disposed to overlap the cell bonding insulating layer 150 in a second direction D2. A lower surface of the cell bonding pad 151 may be coplanar with a lower surface of the cell bonding insulating layer 150. A peripheral bonding pad 251 may be disposed to overlap the peripheral bonding insulating layer 250 in the second direction D2. An upper surface of the peripheral bonding pad 251 may be coplanar with an upper surface of the peripheral bonding insulating layer 250. The cell bonding pad 151 and the peripheral bonding pad 251 may correspond to each other. The cell bonding pad 151 and the peripheral bonding pad 251 may contact each other. A contact face between lower surfaces of the cell bonding insulating layer 150 and the cell bonding pad 151 and upper surfaces of the peripheral bonding insulating layer 250 and the peripheral bonding pad 251 may be the bonding face BS.

A through electrode 300 may connect a first connection pad 310 to a second connection pad 320 and may extend in the first direction D1 in the semiconductor structure 12. The through electrode 300 may penetrate at least part of the semiconductor structure 12 in the first direction D1. For example, the through electrode 300 may penetrate the memory cell structure CS and the peripheral circuit structure PS in the first direction D1. The through electrode 300 may overlap the memory cell structure CS and the peripheral circuit structure PS in the second direction D2 or the third direction D3. The through electrode 300 may be a TSV.

A first surface 300_1 of the through electrode 300 may be coplanar with a second surface 100_2 (for example, an upper surface) of the memory cell structure CS. A second surface 300_2 of the through electrode 300 may be located at a level lower than a second surface 200_2 (for example, a lower surface) of the peripheral circuit substrate 200.

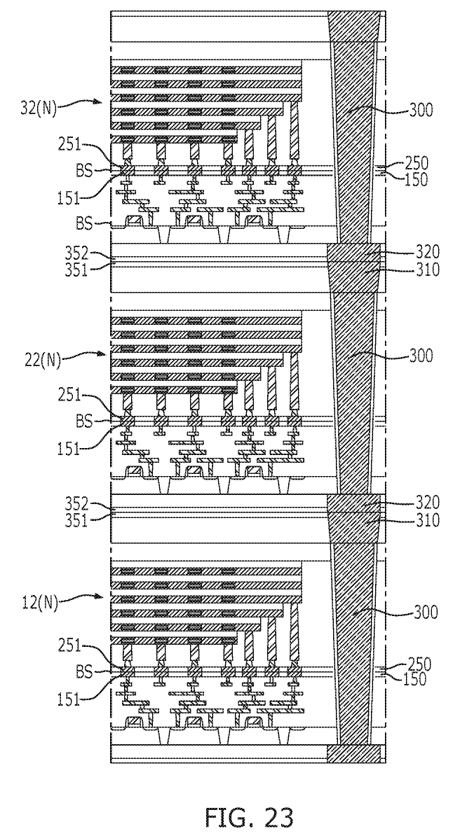

Referring to FIG. 23, semiconductor structures 12, 22, and 32 may each be stacked in the normal state N. That is, a front surface of the first semiconductor structure 12 may be bonded to a rear surface of the second semiconductor structure 22, and a front surface of the second semiconductor structure 22 may be bonded to a rear surface of the third semiconductor structure 32. The plurality of semiconductor structures 12, 22, and 32 may be bonded to one another by the HCB method.

A first connection pad 310 of the first semiconductor structure 12 may be bonded to a second connection pad 320 of the second semiconductor structure 22, and a first bonding insulating layer 351 of the first semiconductor structure 12 may be bonded to a second bonding insulating layer 352 of the second semiconductor structure 22. The first bonding insulating layer 351 of the first semiconductor structure 12 may contact the second bonding insulating layer 352 of the second semiconductor structure 22.

A first connection pad 310 of the second semiconductor structure 22 may be bonded to a second connection pad 320 of the third semiconductor structure 32, and a first bonding insulating layer 351 of the second semiconductor structure 22 may be bonded to a second bonding insulating layer 352 of the third semiconductor structure 32. The first bonding insulating layer 351 of the second semiconductor structure 22 may contact the second bonding insulating layer 352 of the third semiconductor structure 32.

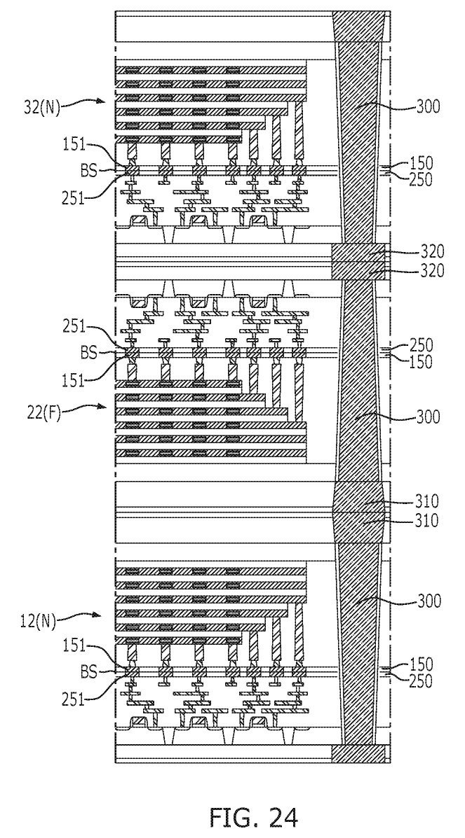

Referring to FIG. 24, the first semiconductor structure 12 may be placed in the normal state N, the second semiconductor structure 22 may be stacked on the first semiconductor structure 12 in the flipped state F, and the third semiconductor structure 32 may be stacked on the second semiconductor structure 22 in the normal state N. That is, the first semiconductor structure 12 and the second semiconductor structure 22 may be bonded front-to-front, and the second semiconductor structure 22 and the third semiconductor structure 32 may be bonded rear-to-rear. The plurality of semiconductor structures 12, 22, and 32 may be bonded to one another by the HCB method.

The respective first connection pads 310 and respective first bonding insulating layers 351 of the first semiconductor structure 12 and the second semiconductor structure 22 may be bonded to each other. The respective second connection pads 320 and respective second bonding insulating layers 352 of the second semiconductor structure 22 and the third semiconductor structure 32 may be bonded to each other.

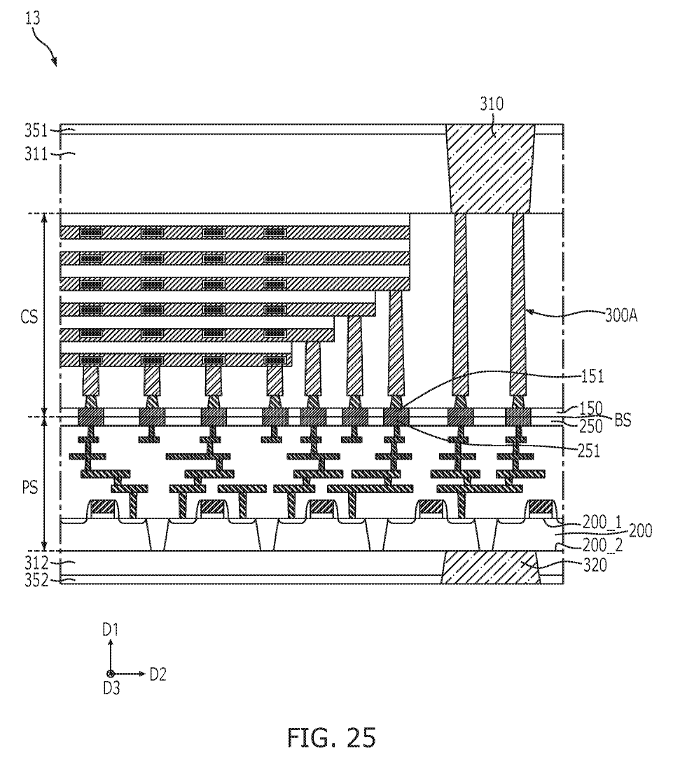

FIGS. 25-27 are diagrams illustrating a semiconductor structure and a semiconductor memory device according to some implementations of the present disclosure.

Referring to FIG. 25, a semiconductor structure 13 according to some implementations of the present disclosure may differ from the implementation of FIG. 22 in a shape of a through electrode 300A. For example, the through electrode 300A may be a contact structure rather than a TSV. In some implementations, the through electrode 300A may include a first connection pad 310 provided as a TSV and a contact structure. In this case, an insulating film may be provided on a side surface of the first connection pad 310.

The semiconductor structure 13 may have a CoP structure in which the memory cell structure CS is disposed on an upper side of the peripheral circuit structure PS. The memory cell structure CS may be disposed such that the first surface 100_1 of the cell substrate 100 faces the first surface 200_1 of the peripheral circuit substrate 200. For example, the memory cell structure CS may be bonded on the peripheral circuit structure PS by the HCB method.

Each of a plurality of through electrodes 300A may be disposed in a corresponding one of a plurality of semiconductor structures 13. The through electrode 300A may penetrate the memory cell structure CS in the first direction D1. Each through electrode 300A may electrically connect the peripheral circuit structure PS to the memory cell structure CS. The through electrode 300A may include a conductive material. For example, the conductive material may include at least one of aluminum, tungsten, and titanium.

The first connection pad 310 may be disposed on the memory cell structure CS. The first connection pad 310 may be electrically connected to the through electrode 300A by contacting the through electrode 300A. A second connection pad 320 may be disposed on a lower surface of the peripheral circuit structure PS. The second connection pad 320 may be disposed on a lower surface of the peripheral circuit substrate 200. The first connection pad 310 and the second connection pad 320 may be aligned in the first direction D1.

The through electrode 300A may be connected to the cell bonding pad 151. The cell bonding pad 151 may be connected to the peripheral bonding pad 251 through the HCB process. Thus, the through electrode 300A may electrically connect the first connection pad 310 to the second connection pad 320 connected to the peripheral wiring structure.

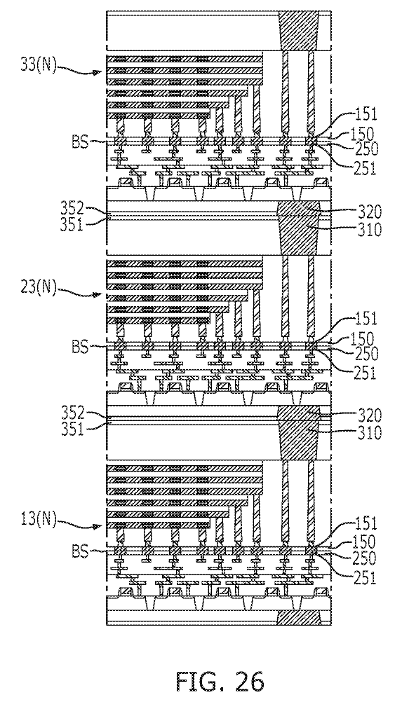

Referring to FIG. 26, semiconductor structures 13, 23, and 33 may each be stacked in the normal state N. That is, a front surface of the first semiconductor structure 13 may be bonded to a rear surface of the second semiconductor structure 23, and a front surface of the second semiconductor structure 23 may be bonded to a rear surface of the third semiconductor structure 33. The plurality of semiconductor structures 13, 23, and 33 may be bonded to one another by the HCB method.

A first connection pad 310 of the first semiconductor structure 13 may be bonded to a second connection pad 320 of the second semiconductor structure 23, and a first bonding insulating layer 351 of the first semiconductor structure 13 may be bonded to a second bonding insulating layer 352 of the second semiconductor structure 23. The first bonding insulating layer 351 of the first semiconductor structure 13 may contact the second bonding insulating layer 352 of the second semiconductor structure 23.

A first connection pad 310 of the second semiconductor structure 23 may be bonded to a second connection pad 320 of the third semiconductor structure 33, and a first bonding insulating layer 351 of the second semiconductor structure 23 may be bonded to a second bonding insulating layer 352 of the third semiconductor structure 33. The first bonding insulating layer 351 of the second semiconductor structure 23 may contact the second bonding insulating layer 352 of the third semiconductor structure 33.

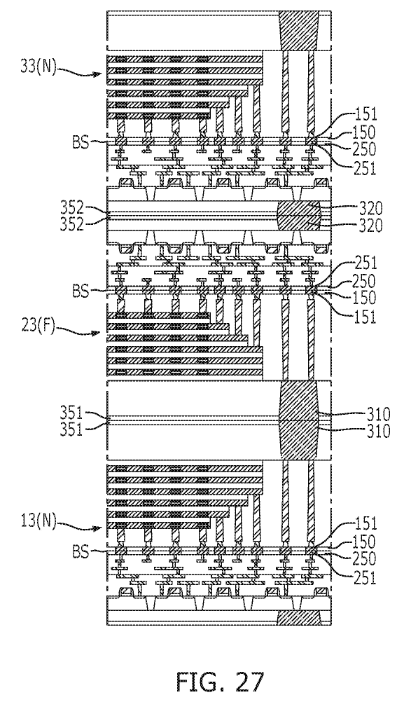

Referring to FIG. 27, the first semiconductor structure 13 may be placed in the normal state N, the second semiconductor structure 23 may be stacked on the first semiconductor structure 13 in the flipped state F, and the third semiconductor structure 33 may be stacked on the second semiconductor structure 23 in the normal state N. That is, the first semiconductor structure 13 and the second semiconductor structure 23 may be bonded front-to-front, and the second semiconductor structure 23 and the third semiconductor structure 33 may be bonded rear-to-rear.

For example, the plurality of semiconductor structures 13, 23, and 33 may be bonded to one another by the HCB method. The respective first connection pads 310 and respective first bonding insulating layers 351 of the first semiconductor structure 13 and the second semiconductor structure 23 may be bonded to each other. The respective second connection pads 320 and respective second bonding insulating layers 352 of the second semiconductor structure 23 and the third semiconductor structure 33 may be bonded to each other.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device comprising:
a plurality of semiconductor structures that are stacked in a first direction that is perpendicular to an upper surface of a cell substrate, each semiconductor structure of the plurality of semiconductor structures comprising (i) a memory cell structure including the cell substrate and (ii) a peripheral circuit structure that overlaps the memory cell structure in the first direction; and
a plurality of through electrodes that extend in the first direction in each of the plurality of semiconductor structures,
wherein the memory cell structure comprises:
a plurality of memory cells that are stacked on the cell substrate and spaced apart in the first direction, each memory cell of the plurality of memory cells comprising a semiconductor pattern including a channel region and a capacitor structure on a first side of the semiconductor pattern,
a plurality of word lines that extend in a second direction parallel to the upper surface of the cell substrate and that surround the channel region, and
a bit line on a second side of the semiconductor pattern that is opposite to the first side of the semiconductor pattern.

2. The semiconductor memory device according to claim 1, wherein each through electrode of the plurality of through electrodes extends into the memory cell structure and the peripheral circuit structure in the first direction.

3. The semiconductor memory device according to claim 1, wherein each through electrode of the plurality of through electrodes comprises a first surface and a second surface opposite to the first surface, wherein a width of each through electrode of the plurality of through electrodes decreases in the first direction from the first surface toward the second surface.

4. The semiconductor memory device according to claim 3, wherein
the peripheral circuit structure comprises a peripheral circuit substrate, at least one peripheral circuit device on the peripheral circuit substrate, and a peripheral wiring structure electrically connected to the at least one peripheral circuit device,
each semiconductor structure of the plurality of semiconductor structures comprises a wiring structure that is stacked on the peripheral circuit structure, and
the first surface of each through electrode of the plurality of through electrodes is coplanar with an interface between the peripheral wiring structure and the wiring structure.

5. The semiconductor memory device according to claim 3, wherein
each semiconductor structure of the plurality of semiconductor structures comprises a wiring structure that is stacked on the peripheral circuit structure, and
an interface between the peripheral circuit structure and the wiring structure is coplanar with the first surface of each through electrode.

6. The semiconductor memory device according to claim 5, wherein a distance from the interface to the second surface of each through electrode of the plurality of through electrodes is greater than a distance from the interface to a lower surface of the peripheral circuit substrate.

7. The semiconductor memory device according to claim 3, wherein each semiconductor structure of the plurality of semiconductor structures further comprises:
a first connection pad that overlaps a through electrode of the plurality of through electrodes in the first direction, and
a second connection pad on the second surface of the through electrode, and
wherein a width of the first connection pad decreases with a decrease in distance to the through electrode along the first direction.

8. The semiconductor memory device according to claim 7, wherein
each semiconductor structure of the plurality of semiconductor structures comprises a bonding insulating layer that overlaps the second connection pad in the second direction.

9. The semiconductor memory device according to claim 7, wherein
the plurality of semiconductor structures comprise a first semiconductor structure and a second semiconductor structure that is stacked on the first semiconductor structure, and
the first connection pad of the first semiconductor structure is in contact with the first connection pad of the second semiconductor structure.

10. The semiconductor memory device according to claim 7, wherein
the plurality of semiconductor structures comprise a first semiconductor structure and a second semiconductor structure that is stacked on the first semiconductor structure, and
the first connection pad of the first semiconductor structure is in contact with the second connection pad of the second semiconductor structure.

11. The semiconductor memory device according to claim 1, wherein
the memory cell structure comprises a cell bonding insulating layer, and
the peripheral circuit structure comprises a peripheral bonding insulating layer that is bonded to the cell bonding insulating layer.

12. The semiconductor memory device according to claim 11, wherein
the memory cell structure comprises a cell bonding pad that overlaps the cell bonding insulating layer in the second direction,
the peripheral circuit structure comprises a peripheral bonding pad that overlaps the peripheral bonding insulating layer in the second direction, and
the cell bonding pad is in contact with the peripheral bonding pad.

13. A semiconductor memory device comprising:
a first semiconductor structure comprising a first memory cell structure and a first peripheral circuit structure that overlaps the first memory cell structure in a first direction;
a second semiconductor structure that is stacked on the first semiconductor structure in the first direction, the second semiconductor structure comprising a second memory cell structure and a second peripheral circuit structure that overlaps the second memory cell structure in the first direction;
a first through electrode that extends into the first memory cell structure and the first peripheral circuit structure in the first direction; and
a second through electrode that extends into the second memory cell structure and the second peripheral circuit structure in the first direction and that is aligned with the first through electrode in the first direction,
wherein each memory cell structure of the first and second memory cell structures comprises:
a plurality of memory cells that are stacked and spaced apart from one another in the first direction, each memory cell of the plurality of memory cells comprising a semiconductor pattern including:
a channel region,
a first source/drain region and a second source/drain region respectively on opposite sides of the channel region, and
a capacitor structure connected to the first source/drain region;
a plurality of word lines that extend in a second direction that intersects with the first direction, wherein the plurality of word lines are stacked and spaced apart from one another in the first direction, wherein the plurality of word lines surround the channel region of each memory cell of the plurality of memory cells; and
a bit line that extends in the first direction and that is connected to the second source/drain region.

14. The semiconductor memory device according to claim 13, wherein
the first semiconductor structure comprises a first wiring structure on a first surface of the first through electrode, a first front-side connection pad on the first wiring structure, and a first back-side connection pad on a second surface of the first through electrode,
the second semiconductor structure comprises a second wiring structure on a first surface of the second through electrode, a second front-side connection pad on the second wiring structure, and a second back-side connection pad on a second surface of the second through electrode, -
a width of the first front-side connection pad decreases with a decrease in distance to the first wiring structure along the first direction, and
a width of the second front-side connection pad decreases with a decrease in distance to the second wiring structure along the first direction.

15. The semiconductor memory device according to claim 14, wherein
the first semiconductor structure comprises a bonding insulating layer that overlaps the first front-side connection pad in the second direction,
the second semiconductor structure comprises a front-side bonding insulating layer that overlaps the second front-side connection pad in the second direction,
the front-side bonding insulating layer is on the bonding insulating layer, and
the second front-side connection pad is on the first front-side connection pad.

16. The semiconductor memory device according to claim 14, wherein
the first semiconductor structure comprises a bonding insulating layer that overlaps the first back-side connection pad in the second direction,
the second semiconductor structure comprises a front-side bonding insulating layer that overlaps the second front-side connection pad in the second direction,
the front-side bonding insulating layer is on the bonding insulating layer, and
the second front-side connection pad is on the first back-side connection pad.

17. The semiconductor memory device according to claim 14, wherein each through electrode of the first through electrode and the second through electrode has a width that decreases in a direction from the first surface toward the second surface.

18. The semiconductor memory device according to claim 17, wherein
the first through electrode overlaps both the first memory cell structure and the first peripheral circuit structure in the second direction, and
the second through electrode overlaps both the second memory cell structure and the second peripheral circuit structure in the second direction.

19. The semiconductor memory device according to claim 13, wherein each through electrode of the first through electrode and the second through electrode comprises a conductive film and an insulating film disposed on a side surface of the conductive film.

20. A semiconductor package, comprising:
a package substrate;
a semiconductor memory device including a plurality of semiconductor structures that are stacked on the package substrate in a first direction that is perpendicular to an upper surface of the package substrate; and
a plurality of through electrodes that are electrically connected to the plurality of semiconductor structures,
wherein each semiconductor structure of the plurality of semiconductor structures comprises:
a memory cell structure including a cell substrate,
a peripheral circuit structure that overlaps the memory cell structure in the first direction, and
a wiring structure that is electrically connected to both the memory cell structure and the peripheral circuit structure,
wherein the memory cell structure comprises:
a plurality of memory cells that are spaced apart from one another in the first direction, each memory cell of the plurality of memory cells comprising a semiconductor pattern including:
a channel region,
a first source/drain region and a second source/drain region disposed on opposite sides of the channel region, and
a capacitor structure connected to the first source/drain region;
a plurality of word lines that extend in a second direction that intersects with the first direction and that are spaced apart from one another in the first direction, wherein the plurality of word lines surround the channel region; and
a bit line that extends in the first direction and is connected to the second source/drain region.
